(19) United States
(12) Patent Application Publication
(10) Pub. No.: US 2025/0372474 A1
(43) Pub. Date: Dec. 4, 2025

(54) Modular Heatsink for Integrated Circuit Package

(71) Applicant: Altera Corporation, San Jose, CA (US)

(72) Inventors: Srinivasarao Konakalla, Bangalore (IN); Krishnakumar Varadarajan, Bangalore (IN)

(21) Appl. No.: 18/677,669

(22) Filed: May 29, 2024

(51) Int. Cl. H01L 23/367; H01L 23/373

(52) U.S. Cl. CPC H01L 23/3672; H01L 23/3736

(57) ABSTRACT

Systems and methods for a modular heatsink system for integrated circuit devices are provided. A modular heatsink system may include a base spreader to attach to an integrated circuit package die. A secondary heat dissipation device may be selectively attachable to the base spreader. The base spreader dissipates a first amount of heat from the integrated circuit package die when the secondary heat dissipation device is not mated to the base spreader. The base spreader and the secondary heat dissipation device collectively dissipate a greater amount of heat when the secondary heat dissipation device is mated to the base spreader.

### BACKGROUND

This disclosure relates generally to a heatsink composed of one or more modular components to dissipate heat from integrated circuit (IC) devices such as processors, application specific integrated circuits (ASICs), and programmable logic devices (PLDs) such as Field programmable Gate Arrays (FPGAs).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are ubiquitous in modern electronics. To support the various use cases of different customers, manufacturers of integrated circuits will often produce many versions of a similar integrated circuit device with different levels of performance and power consumption. For example, the manufacturer may offer lower-power, lower-performance integrated circuit devices and higher-power, higher-performance integrated circuit devices. Because operating an integrated circuit device generates heat, a heatsink is usually attached to the integrated circuit device to dissipate the heat. The heatsink may be designed for a worst-case scenario to ensure that the integrated circuit device does not exceed a specified temperature limit during operation. In many cases, this means that every version of a similar integrated circuit device may use a larger, costly heatsink designed for a worst-case scenario.

### BRIEF DESCRIPTION OF THE DRAWINGS

Various aspects of this disclosure may be better understood upon reading the following detailed description and upon reference to the drawings in which:

FIG. 1 is a block diagram of a lower-power integrated circuit system that uses a modular heatsink with a base spreader to dissipate heat;

FIG. 2 is a block diagram of a medium-power integrated circuit system that uses a modular heatsink with the base spreader and a fan to dissipate heat;

FIG. 3 is a block diagram of a higher-power integrated circuit system that uses a modular heatsink with the base spreader, the fan, and an additional heatsink structure to dissipate heat;

FIG. 4 is a side view of the lower-power integrated circuit system having the modular heatsink with the base spreader to dissipate heat;

FIG. 5 is an exploded side view of the medium-power integrated circuit system having the modular heatsink with the base spreader and the fan to dissipate heat;

FIG. 6 is an attached side view of the medium-power integrated circuit system having the modular heatsink with the base spreader and the fan to dissipate heat;

FIG. 7 is an exploded side view of the higher-power integrated circuit system having the modular heatsink with the base spreader, the fan, and the additional heatsink structure to dissipate heat;

FIG. 8 is an attached side view of the higher-power integrated circuit system having the complete assembly of the modular heatsink with the base spreader, the fan, and the additional heatsink structure to dissipate heat;

FIG. 9 is a perspective view of the fan with the additional heatsink structure with a close-up view of the additional heatsink structure;

FIG. 10 is a flowchart of a method for manufacturing an integrated circuit system having a modular heatsink based on the power level of the integrated circuit system; and

FIG. 11 is a block diagram of a data processing system incorporating the integrated circuit system.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

This disclosure relates to a modular heatsink that can easily scale to dissipate heat from lower-power to higher-power integrated circuit devices. Many types of integrated circuit devices, including processors, memory, network interface devices, and field programmable gate arrays (FPGAs) used in a Peripheral Component Interconnect Express (PCIe) card form factor for servers have gained significant traction in the data center and server industry. The broad range of applications and wide variety of use cases translates to many of these products, such as FPGA products, having a variety of performance and power levels. This is especially true for devkit designs where the vendor has to support a wide variety of end customer use cases. Currently, customers often design their heat sinks based on the maximum use case, leaving them with an increased size and cost when the same device is used in a lower-power regime. The other option is to maintain an inventory of multiple distinct thermal heat sink solutions, which is also expensive.

To enable efficient heat dissipation across a range of different performance and power levels, a low-cost modular heatsink thermal solution design may provide customers with flexibility tailored to specific scenarios. Indeed, the low-cost modular heatsink of this disclosure may scale to support power consumption of the component varying from 5-10 W in the lower range to 50-70 W or beyond in the higher range. For products with relatively lower power levels, the modular heatsink may include a simple spreader or an anodized base spreader with sparsely placed thicker fins to passively dissipate heat. For products with relatively higher power levels, a fan and/or additional heatsink structure may be mated with the base spreader to dissipate even more heat. In addition, the base spreader of the modular heatsink of this disclosure may help to enhance the capability in the low end from a typical 3-5 W range by 50% or more.

FIG. 1 illustrates a modular heatsink system 10 for a lower-power integrated circuit package die 12A having a first power level. By way of example, the lower-power integrated circuit package die 12A may generate less than 8 Watts (W) of heat. A base spreader 14 may be attached to the lower-power integrated circuit package die 12A to passively dissipate the heat. Collectively, the base spreader 14 and the lower-power integrated circuit package die 12A may have a height less than that of one server rack unit (1 U) (about 1.75 inches).

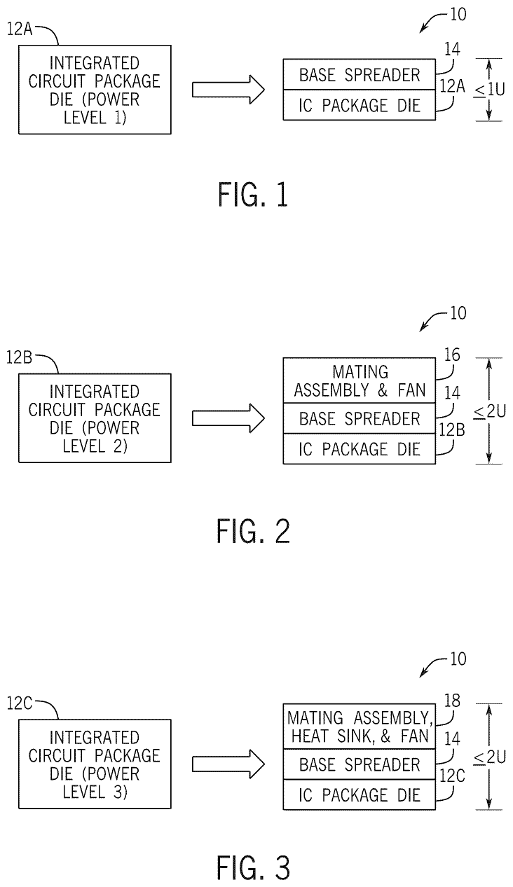

The base spreader 14 may act as a component of a modular heatsink that, when paired with a secondary heat dissipation device, may scale to accommodate heat dissipation for integrated circuit devices with higher power consumption. For example, FIG. 2 illustrates the modular heatsink system 10 applied to a medium-power integrated circuit package die 12B having a second, higher power level. By way of example, the medium-power integrated circuit package die 12B may generate less than around 20 W. To dissipate the heat generated by the medium-power integrated circuit package die 12B, the base spreader 14 may be attached to the medium-power integrated circuit package die 12B. A secondary heat dissipation device in the form of a mating assembly and fan structure 16 may attach to the base spreader 14. Air circulating from the mating assembly and fan structure 16 over the base spreader 14 may dissipate the heat. Collectively, the base spreader 14, the mating assembly and fan structure 16, and the medium-power integrated circuit package die 12B may have a height less than that of two server rack units (2 U) (about 3.5 inches).

Similarly, FIG. 3 illustrates the modular heatsink system 10 applied to a higher-power integrated circuit package die 12C having a third, higher power level. By way of example, the higher-power integrated circuit package die 12C may generate less than around 65 W. To dissipate the heat generated by the higher-power integrated circuit package die 12C, the base spreader 14 may be attached to the higher-power integrated circuit package die 12C. A secondary heat dissipation device in the form of a mating assembly, additional heatsink structures, and fan structure 18 may attach to the base spreader 14. Air circulating from the mating assembly, additional heatsink structure, and fan structure 18 over the base spreader 14 may dissipate the heat. Collectively, the base spreader 14, the mating assembly, additional heatsink structures, and fan structure 18, and the higher-power integrated circuit package die 12C may have a height less than that of two server rack units (2 U) (about 3.5 inches).

Although the integrated circuit package die 12A, 12B, and 12C are described as having certain power levels, it should be understood that the modular heatsink system 10 may have modular heatsink components that may dissipate more or less heat depending on the particular design and implementation (e.g., size, materials). Thus, the integrated circuit package die 12A, 12B, and 12C may operate at different power levels than those mentioned above in some embodiments based on the design of the modular heatsink system 10.

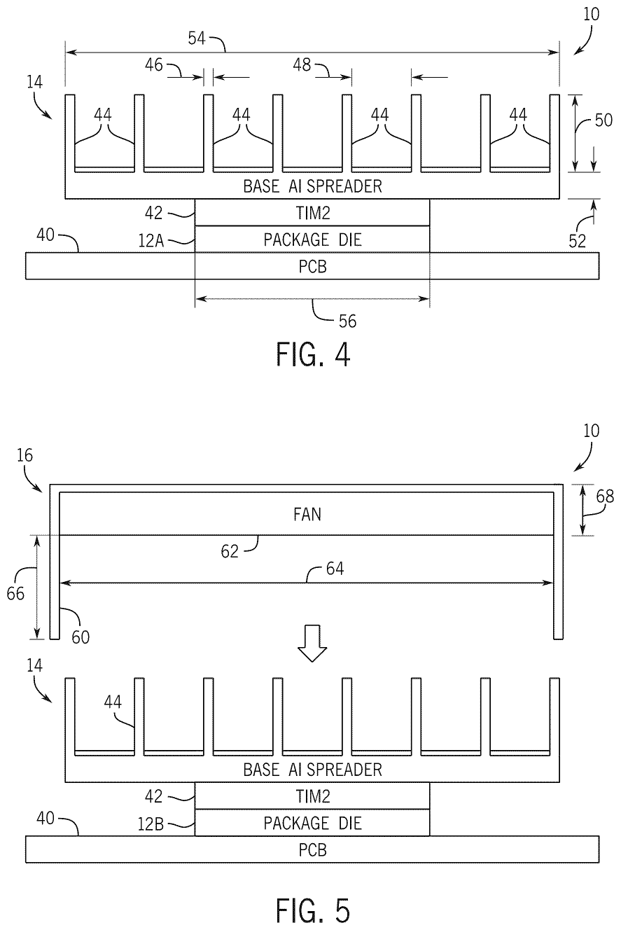

FIG. 4 illustrates a side view of the base spreader 14 on the lower-power integrated circuit package die 12A. The lower-power integrated circuit package die 12A is installed on a printed circuit board 40. A thermal coupling material 42 joins the lower-power integrated circuit package die 12A to the base spreader 14. The thermal coupling material 42 may be any suitable substance that allows for efficient heat transfer from the lower-power integrated circuit package die 12A to the base spreader 14, and may include any suitable thermal interface materials such as thermal epoxy, thermal grease, and/or gap filler.

The base spreader 14 may take any suitable form and may be made from any suitable heat-conducting material. For example, the base spreader 14 may be made from anodized aluminum, non-anodized aluminum, copper, steel, or any other suitable material. Fins 44 may further increase the surface area of the base spreader 14, allowing the base spreader 14 to passively dissipate heat. The number, thickness, and spacing of the fins 44 may be selected to allow for efficient radiative cooling to for a desired amount of heat. For example, there may be 6-8 fins 44 having a thickness 46 of between about 0.4-2.0 mm and a spacing 48 of between 10-15 mm apart. Indeed, the relatively high thickness of the thickness 46 may permit the base spreader 14 to be die cast or machined at relatively low cost. To save on manufacturing and material costs, the base spreader 14 may have fins 44 with a thickness 46 of between 0.4-0.7 mm. The fins 44 of the base spreader 14 may have a height 50 of between 7-10 mm and a base of the base spreader 14 may have a height 52 of between 3-5 mm. An overall width 54 of the base spreader 14 may be approximately three to five times a width 56 of the integrated circuit package die to which it is attached. For example, if the width 56 of the lower-power integrated circuit package die 12A is 30 mm, the width 54 of the base spreader 14 may be between about 90-150 mm. If the width 56 of the lower-power integrated circuit package die 12A is 40 mm, the width 54 of the base spreader 14 may be between about 120-200 mm. The base spreader 14 may be manufactured in any suitable manner. For example, the base spreader may be manufactured using die casting, machining, additive manufacturing, forging, skiving, or stamping and soldering.

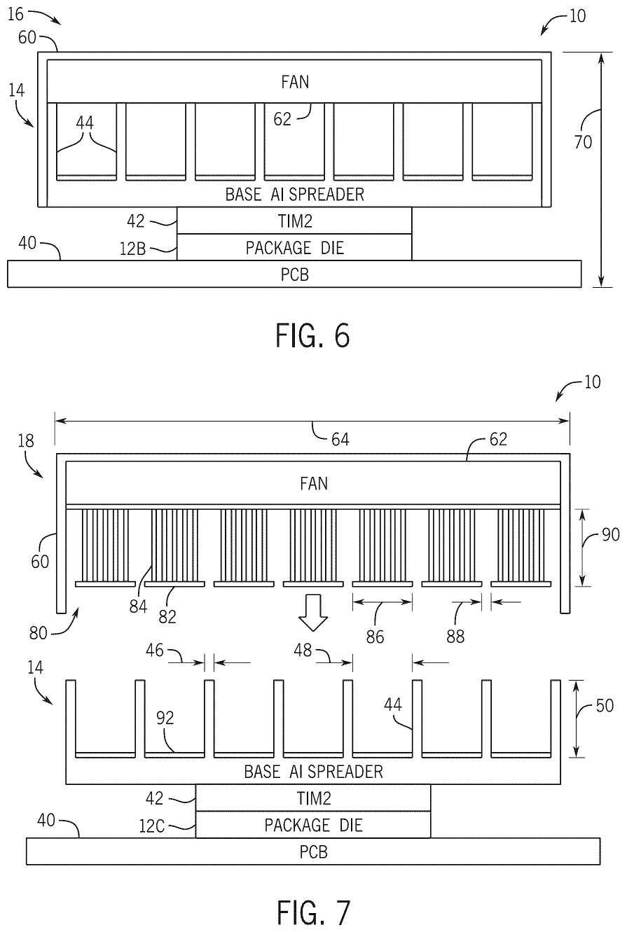

FIG. 5 illustrates an exploded side view of the modular heatsink system 10 with the medium-power integrated circuit package die 12B having the base spreader 14 and the mating assembly and fan structure 16. The base spreader 14 may be as described with respect to FIG. 4. To dissipate even more power than that which is dissipated by the base spreader 14 alone, the base spreader 14 may be attached to the mating assembly and fan structure 16. The mating assembly and fan structure 16 includes a mating assembly 60 (e.g., shroud) and a fan 62. The mating assembly 60 has a width 64 that is at least as wide as the width 54 of the base spreader 14 (e.g., as shown in FIG. 4). In some embodiments, the width 64 of the mating assembly 60 may be close enough to the width 54 of the base spreader 14 to be attached to the outer fins 44 of the base spreader 14 by an adhesive (e.g., thermal epoxy, thermal grease). A height 66 of the mating assembly 60 to the fan 62 may be substantially high enough to equal or exceed the height 50 of the fins 44 of the base spreader 14. In one example, the height 66 is equal to about 12 mm. A height 68 of the fan 62 may be approximately 12-14 mm. The fan 20 allow the base spreader 14 to dissipate more heat (e.g., if the base spreader 14 dissipates about 8 W passively, it may dissipate about 20 W with the fan 62 actively passing air across the fins 44 of the base spreader 14). FIG. 6 illustrates a side view of the modular heatsink system 10 with the mating assembly and fan structure 16 fully attached to the base spreader 14. A total height 70 may be less than or equal to the height of two rack units (2 U).

FIG. 7 illustrates an exploded side view of the modular heatsink system 10 with the higher-power integrated circuit package die 12C having the base spreader 14 mated with the mating assembly, additional heatsink structures, and fan structure 18. The base spreader 14 may be as described with respect to FIG. 4. To dissipate even more power than that which is dissipated by the base spreader 14 alone or the base spreader 14 with the fan 62, there may be additional heatsink structures 80 that can dissipate even more heat. The mating assembly, additional heatsink structure, and fan structure 18 includes the mating assembly 60 (e.g., shroud), fan 62, and additional heatsink structures 80. The mating assembly 60 has the width 64 that is at least as wide as the width 54 of the base spreader 14 (e.g., as shown in FIG. 4). As mentioned above with reference to FIG. 5, in some embodiments, the width 64 of the mating assembly 60 may be close enough to the width 54 of the base spreader 14 to be attached to the outer fins 44 of the base spreader 14 by an adhesive (e.g., thermal epoxy, thermal grease). Additionally or alternatively, adhesive may not be used between the outer fins 44 and the mating assembly 60.

The additional heatsink structures 80 may include a bottom plate 82 attached to a number of relatively thin fins 84 (e.g., having a thickness of less than approximately 0.4 mm). The bottom plate 82 and the thin fins 84 may be made of any suitable heat-conductive material, such as anodized aluminum, non-anodized aluminum, copper, steel, or any other suitable material. To reduce manufacturing costs, in some cases, the bottom plate 82 and thin fins 84 may be made from non-anodized aluminum and the base spreader 14 may be made from anodized aluminum. The bottom plates 82 may have a width 86 that is less than the spacing 48 between the thicker fins 44 of the base spreader 14. A spacing 88 between the bottom plates 82 may be at least as wide as the thickness 46 of the fins 44 of the base spreader 14. A height 90 of the bottom plate 82 and thin fins 84 may be at least as great as the height 50 of the fins 44 of the base spreader 14. Thermal interface material 92 may attach the bottom plates 82 of the additional heatsink structures 80 to the base spreader 14.

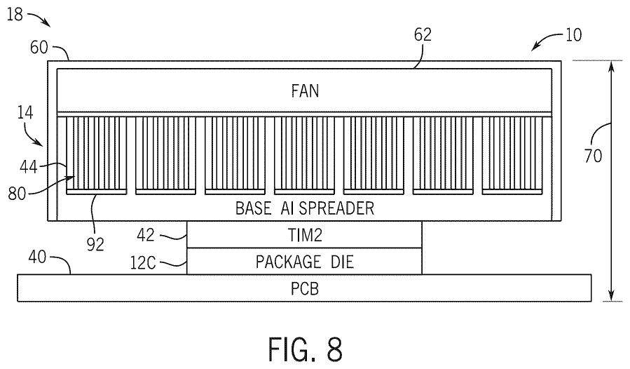

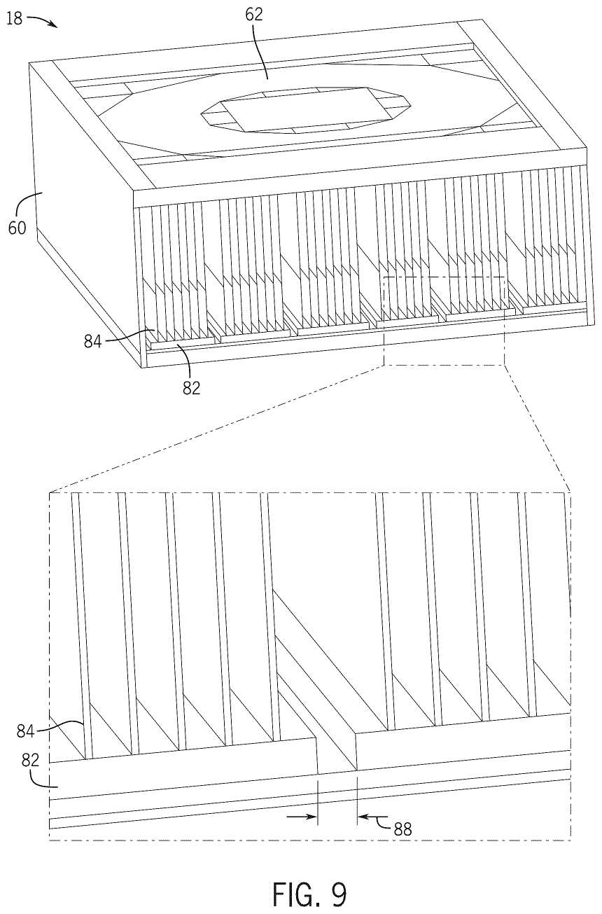

The fan 20 and the additional heatsink structures 80 allow the base spreader 14 to dissipate more heat (e.g., if the base spreader 14 dissipates about 8 W passively, it may dissipate over 65 W with the fan 62 actively passing air across the thin fins 84 of the additional heat structures 80 and the fins 44 of the base spreader 14). FIG. 8 illustrates a side view of the modular heatsink system 10 with the mating assembly, fan, and additional heatsink structures 18 fully attached to the base spreader 14. The total height 70 may be less than or equal to the height of two rack units (2 U).

FIG. 9 is a perspective view of the mating assembly, additional heatsink structures, and fan structure 18. As seen in FIG. 9, the fan 62 may be surrounded by and attached to the mating assembly 60. The thin fins 84 may attach to the bottom plates 82, which may be separated from one another by the spacing 88. When the mating assembly, additional heatsink structures, and fan structure 18 is assembled on top of the base spreader 14, the bottom plates 82 rest on the base spreader 14. The grooves formed between the bottom plates 82 (e.g., having the spacing 88) aid the proper insertion of the extended thick fins 44 of the base spreader 14. Additionally, a soft gap pad thermal interface material 92 (e.g., as shown in FIGS. 7 and 8) is placed between the base spreader 14 and the mating assembly, additional heatsink structures, and fan structure 18 bottom plates 82 to facilitate effective heat transfer.

The manufacturing of the additional heatsink structure 80 can be made of zipper fins 84 stacked and soldered to the bottom plate 82 and joined on top to make a single part. Then the additional heatsink structure 80 can be assembled to the mating assembly 60 (e.g., shroud) and fan 62 subassembly to create an add-on solution for high-end applications as a drop-in option.

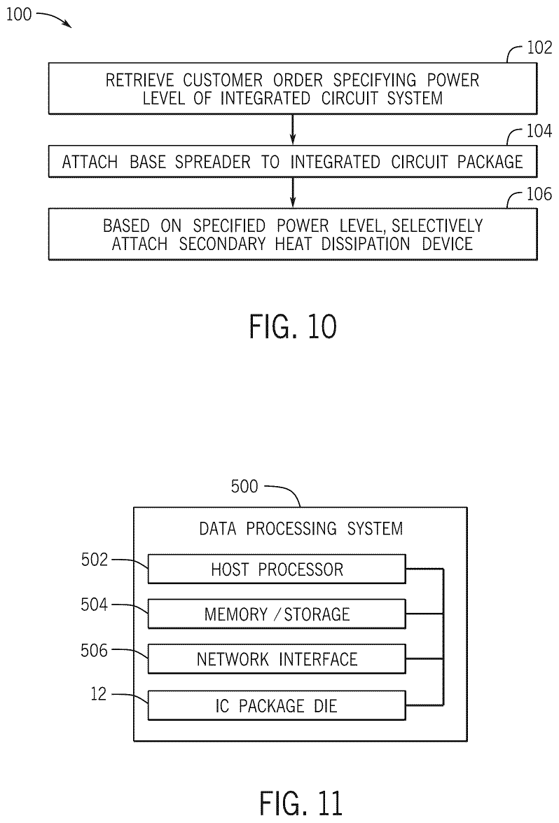

A flowchart 100 shown in FIG. 10 illustrates one manner of manufacturing the modular heatsink system 10. A manufacturer may receive a customer order specifying a product having a particular power level (block 102). A base spreader may be attached to the integrated circuit package die 12 (block 104). If the integrated circuit package die that has been ordered is a relatively lower power integrated circuit device, the base spreader may suffice to dissipate power. Otherwise, a secondary heat dissipation device (e.g., fan, additional heatsink structures and fan) may be attached to the base spreader (block 106). This may enable scalable and cost-efficient power dissipation across a range of products of varying power levels.

An integrated circuit including the modular heatsink system of this disclosure may be a component included in a data processing system, such as a data processing system 500, shown in FIG. 11. The data processing system 500 may include the integrated circuit system 12 (e.g., a programmable logic device, an ASIC, a processor), a host processor 502, memory and/or storage circuitry 504, or a network interface 506. The modular heatsink system of this disclosure may be part of the integrated circuit system 12 (e.g., a programmable logic device), the host processor 502, the memory and/or storage circuitry 504, or the network interface 506, or another integrated circuit such as a graphics processing unit (GPU) or AI application specific integrated circuit (ASIC). The data processing system 500 may include more or fewer components (e.g., electronic display, user interface structures, application specific integrated circuits (ASICs)). The host processor 502 may include any processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as different cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. A modular heatsink system comprising:
a base spreader to attach to an integrated circuit package die; and
a secondary heat dissipation device selectively attachable to the base spreader;

wherein the base spreader is to dissipate a first amount of heat from the integrated circuit package die when the secondary heat dissipation device is not mated to the base spreader, and wherein the base spreader and the secondary heat dissipation device are collectively to dissipate a second amount of heat from the integrated circuit package die that is greater than the first amount of heat when the secondary heat dissipation device is mated to the base spreader.

EXAMPLE EMBODIMENT 2. The modular heatsink system of example embodiment 1, wherein the base spreader comprises fins of a first thickness and the secondary heat dissipation device comprises fins of a second thickness thinner than the first thickness.

EXAMPLE EMBODIMENT 3. The modular heatsink system of example embodiment 2, wherein the first thickness is greater than 0.4 mm and the second thickness is 0.4 mm or thinner.

EXAMPLE EMBODIMENT 4. The modular heatsink system of example embodiment 1, wherein the base spreader comprises anodized aluminum.

EXAMPLE EMBODIMENT 5. The modular heatsink system of example embodiment 1, wherein the base spreader comprises a die-cast module.

EXAMPLE EMBODIMENT 6. The modular heatsink system of example embodiment 1, wherein the base spreader comprises fins separated from one another by at least 10 mm.

EXAMPLE EMBODIMENT 7. The modular heatsink system of example embodiment 1, wherein the base spreader comprises fins of a first thickness and the secondary heat dissipation device comprises a plurality of plates separated by a spacing equal to or greater than the first thickness, wherein the plurality of plates are configurable to fit between the fins of the base spreader and mate to the base spreader between the fins of the base spreader.

EXAMPLE EMBODIMENT 8. The modular heatsink system of example embodiment 1, wherein the base spreader and the secondary heat dissipation device are to actively dissipate the second amount of heat using a fan of the secondary heat dissipation device when the secondary heat dissipation device is mated to the base spreader.

EXAMPLE EMBODIMENT 9. The modular heatsink system of example embodiment 1, wherein a height of the base spreader attached to the integrated circuit package die is less than or equal to one rack unit (1 U).

EXAMPLE EMBODIMENT 10. The modular heatsink system of example embodiment 1, wherein a height of the secondary heat dissipation device attached to the base spreader attached to the integrated circuit package die is less than or equal to two rack units (2 U).

EXAMPLE EMBODIMENT 11. The modular heatsink system of example embodiment 1, wherein the first amount of heat comprises less than or equal to 8 W and the second amount of heat comprises greater than or equal to 60 W.

EXAMPLE EMBODIMENT 12. A method comprising:
providing an integrated circuit package die;
providing a base spreader of a modular heatsink system to couple to the integrated circuit package die; and
based on a power consumption level of the integrated circuit package die, selectively providing or not providing a secondary heat dissipation device of the modular heatsink system to couple to the base spreader.

EXAMPLE EMBODIMENT 13. The method of example embodiment 12, wherein the base spreader comprises:
anodized aluminum; or
anodized copper; or
both.

EXAMPLE EMBODIMENT 14. The method of example embodiment 13, wherein the base spreader comprises a single die-cast object or a single machined object.

EXAMPLE EMBODIMENT 15. The method of example embodiment 12, wherein the secondary heat dissipation device comprises a mating assembly, additional heatsink structures, and a fan.

EXAMPLE EMBODIMENT 16. A modular heatsink system comprising:
a die-cast base spreader comprising anodized aluminum and including a plurality of fins to dissipate heat from an integrated circuit package die.

EXAMPLE EMBODIMENT 17. The modular heatsink system of example embodiment 16, wherein the plurality of fins have a thickness greater than 0.4 mm.

EXAMPLE EMBODIMENT 18. The modular heatsink system of example embodiment 16, wherein the plurality of fins are spaced at least 10 mm apart.

EXAMPLE EMBODIMENT 19. The modular heatsink system of example embodiment 16, comprising a secondary heat dissipation device comprising a mating assembly to couple to the die-cast base spreader and a fan.

EXAMPLE EMBODIMENT 20. The modular heatsink system of example embodiment 19, wherein the secondary heat dissipation device comprises a plurality of thin fans having a thickness of less than 0.4 mm.

What is claimed is:

1. A modular heatsink system comprising:
a base spreader to attach to an integrated circuit package die; and
a secondary heat dissipation device selectively attachable to the base spreader;
wherein the base spreader is to dissipate a first amount of heat from the integrated circuit package die when the secondary heat dissipation device is not mated to the base spreader, and wherein the base spreader and the secondary heat dissipation device are collectively to dissipate a second amount of heat from the integrated circuit package die that is greater than the first amount of heat when the secondary heat dissipation device is mated to the base spreader.

2. The modular heatsink system of claim 1, wherein the base spreader comprises fins of a first thickness and the secondary heat dissipation device comprises fins of a second thickness thinner than the first thickness.

3. The modular heatsink system of claim 2, wherein the first thickness is greater than 0.4 mm and the second thickness is 0.4 mm or thinner.

4. The modular heatsink system of claim 1, wherein the base spreader comprises anodized aluminum.

5. The modular heatsink system of claim 1, wherein the base spreader comprises a die-cast module.

6. The modular heatsink system of claim 1, wherein the base spreader comprises fins separated from one another by at least 10 mm.

7. The modular heatsink system of claim 1, wherein the base spreader comprises fins of a first thickness and the secondary heat dissipation device comprises a plurality of plates separated by a spacing equal to or greater than the first thickness, wherein the plurality of plates are configurable to fit between the fins of the base spreader and mate to the base spreader between the fins of the base spreader.

8. The modular heatsink system of claim 1, wherein the base spreader and the secondary heat dissipation device are to actively dissipate the second amount of heat using a fan of the secondary heat dissipation device when the secondary heat dissipation device is mated to the base spreader.

9. The modular heatsink system of claim 1, wherein a height of the base spreader attached to the integrated circuit package die is less than or equal to one rack unit (1 U).

10. The modular heatsink system of claim 1, wherein a height of the secondary heat dissipation device attached to the base spreader attached to the integrated circuit package die is less than or equal to two rack units (2 U).

11. The modular heatsink system of claim 1, wherein the first amount of heat comprises less than or equal to 8 W and the second amount of heat comprises greater than or equal to 60 W.

12. A method comprising:
providing an integrated circuit package die;
providing a base spreader of a modular heatsink system to couple to the integrated circuit package die; and
based on a power consumption level of the integrated circuit package die, selectively providing or not providing a secondary heat dissipation device of the modular heatsink system to couple to the base spreader.

13. The method of claim 12, wherein the base spreader comprises:
anodized aluminum; or
anodized copper; or
both.

14. The method of claim 13, wherein the base spreader comprises a single die-cast object or a single machined object.

15. The method of claim 12, wherein the secondary heat dissipation device comprises a mating assembly, additional heatsink structures, and a fan.

16. A modular heatsink system comprising:
a die-cast base spreader comprising anodized aluminum and including a plurality of fins to dissipate heat from an integrated circuit package die.

17. The modular heatsink system of claim 16, wherein the plurality of fins have a thickness greater than 0.4 mm.

18. The modular heatsink system of claim 16, wherein the plurality of fins are spaced at least 10 mm apart.

19. The modular heatsink system of claim 16, comprising a secondary heat dissipation device comprising a mating assembly to couple to the die-cast base spreader and a fan.

20. The modular heatsink system of claim 19, wherein the secondary heat dissipation device comprises a plurality of thin fans having a thickness of less than 0.4 mm.
